(19) United States
(12) Patent Application Publication
(10) Pub. No.: US 2004/0203214 A1
(43) Pub. Date: Oct. 14, 2004

(54) Method of manufacturing semiconductor device

(75) Inventors: Katsuhiko Iizuka, Ora-gun (JP); Kazutomo Goshima, Ora-gun (JP); Toshimitsu Taniguchi, Ora-gun (JP); Toshiharu Oya, Ota-shi (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-city (JP)

(21) Appl. No.: 10/755,680

(22) Filed: Jan. 13, 2004

(30) Foreign Application Priority Data
Jan. 15, 2003 (JP) 2003-006653

(51) Int. Cl. H01L 21/20

(52) U.S. Cl. 438/384; 438/385; 438/382

(57) ABSTRACT

The invention is to obtain a resistor element having high resistance, a low temperature coefficient, and high uniformity of sheet resistance in a wafer. A field oxide film is formed on a semiconductor substrate. On the field oxide film a non-doped silicon film is formed by a LPCVD method. The silicon film is made of an amorphous silicon film or a polysilicon film. BF2⁺ is ion implanted in this silicon film. Then, either before or after this ion implantation, N₂ annealing is performed at low temperature between 650 and 750° C.

### BACKGROUND OF THE INVENTION

1. Field of the Invention:

The present invention relates to a method of manufacturing a semiconductor device, particularly to a method of manufacturing a semiconductor device having a resistor element made of a silicon film having a low temperature coefficient.

2. Description of the Related Art

A polysilicon resistor element formed on a semiconductor substrate has been used as a resistor element for configuring a variety of LSI circuits, for example, a differential amplifier or a reference voltage generating circuit. For realizing the LSI circuit with high precision, a temperature coefficient of the polysilicon resistor element need be reduced.

There has been known a technology of reducing the temperature coefficient of the polysilicon resistor element by controlling the dose of an impurity when an ion-implantation in the non-doped polysilicon film is performed.

However, when the dose of the impurity is controlled for reducing the temperature coefficient, generally, the dose need be increased substantially, thereby reducing sheet resistance Rs of the polysilicon resistor element. Therefore, for obtaining the polysilicon resistor element having high resistance, the pattern area need be made large, taking high costs.

### SUMMARY OF THE INVENTION

The invention provides a method of manufacturing a semiconductor device. The method includes forming a first insulating film on a semiconductor substrate, forming a non-doped silicon film on the first insulating film, performing an ion implantation of a p-type impurity in the silicon film, annealing the ion-implanted silicon film in a nitrogen atmosphere at such a temperature that the p-type impurity implanted in the silicon film is diffused uniformly in the semiconductor substrate while the silicon film is exposed to the nitrogen atmosphere, and forming a second insulating film on the silicon film. Alternatively, the nitrogen annealing may be performed prior to the ion implantation, or the nitrogen annealing may not be performed while the silicon film is exposed.

### BRIEF DESCRIPTION OF THE DRAWINGS

FIG. 1 is a cross-sectional view of a step of a manufacturing method of a semiconductor device of an embodiment of the invention.

FIG. 2 is a cross-sectional view of a manufacturing step following the step of FIG. 1.

FIG. 3 is a cross-sectional view of a manufacturing step following the step of FIG. 2.

FIG. 4 is a cross-sectional view of a manufacturing step following the step of FIG. 3.

FIG. 5 is a cross-sectional view of a manufacturing step following the step of FIG. 4.

FIG. 6 is a plan view explaining the device intermediate shown in FIG. 5.

FIG. 7 lists examination results of the manufacturing method of the semiconductor device of the embodiment with varying processing parameters.

### DETAILED DESCRIPTION OF THE INVENTION

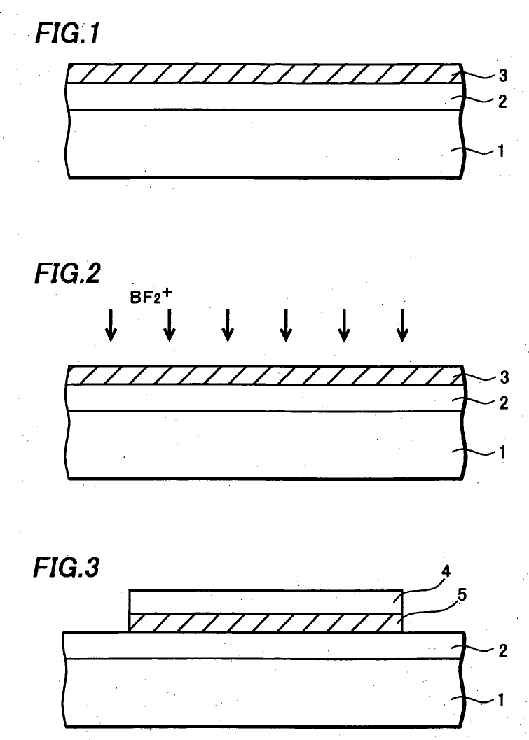

Next, a manufacturing method of a semiconductor device of an embodiment of the invention will be described with reference to the drawings in detail. First, as shown in FIG. 1, a field oxide film 2 is formed on a semiconductor substrate 1 such as a silicon substrate. The field oxide film 2 is formed, for example, by thermal oxidation by a LOCOS (local oxidation of silicon) method etc. On the field oxide film 2, a non-doped silicon film 3 is formed by a LPCVD (low pressure chemical vapor deposition) method. The silicon film 3 is made of an amorphous silicon film or a polysilicon film. The amorphous silicon film is deposited at a temperature of 500 to 550° C., and the polysilicon film is deposited at a temperature higher than the amorphous silicon film, i.e.: approximately 610° C.

Then, as shown in FIG. 2, a p-type impurity, for example, boron (B⁺) or boron difluoride (BF2⁺) is ion implanted in the silicon film 3. Either before or after this ion implantation, N₂ annealing is performed with the silicon film 3 being exposed. Alternatively, annealing including the N₂ annealing is not performed under the condition that the silicon film 3 is exposed. Conditions of the ion implantation and the annealing will be described later.

Next, as shown in FIG. 3, a photoresist film 4 is formed on a region of the silicon film 3, which is to be formed with a resistor element. The silicon film 3 is then dry etched using the photoresist film 4 as a mask, thereby forming a silicon resistor film 5 (amorphous silicon resistor film or polysilicon resistor film).

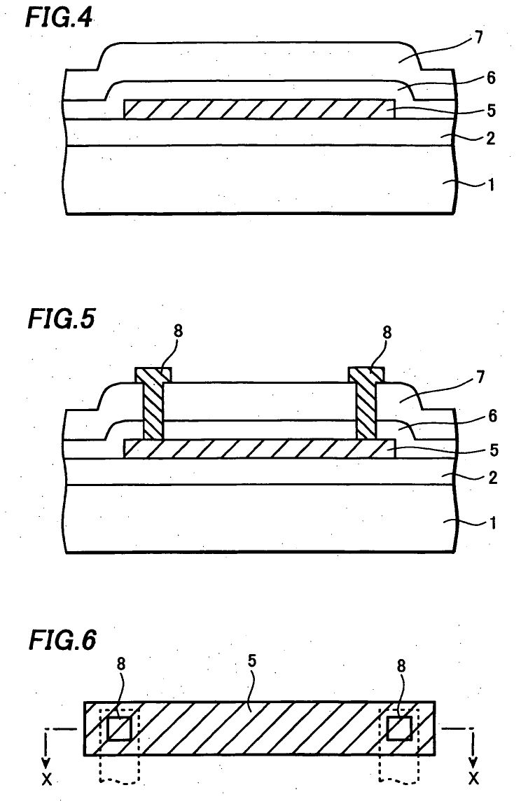

As shown in FIG. 4, an insulating film is formed on the silicon resistor film 5. This insulating film is a laminated film of, for example, a TEOS (tetraethoxysilane) film 6 and a BPSG (borophosphosilicate glass) film 7.

As shown in FIG. 5, a contact hole is formed in the TEOS film 6 and the BPSG film 7 above the silicon resistor film 5, and an electrode 8 for applying a voltage, such as an aluminum electrode, is formed. Here, after the contact hole is formed, H₂ annealing is performed before forming the electrode 8. This H₂ annealing is a heat treatment for lowering an interface state, using H2 as forming gas. The H₂ annealing is performed under the condition that H2 concentration is 4 to 12%, the temperature is 400 to 450° C., and the processing time is 60 to 100 minutes. FIG. 6 is a plan view of the resistor element. FIG. 5 is a cross-sectional view along line X-X of FIG. 6.

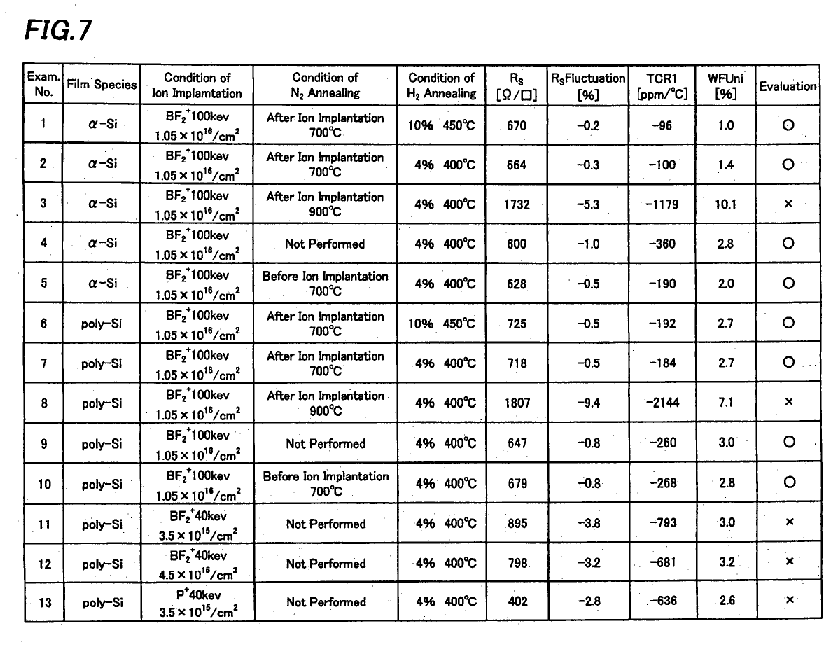

Next, the results of examinations (Nos. 1 to 13) performed according to the above processing steps will be described with reference to FIG. 7. In FIG. 7, “condition of ion implantation” corresponds to the condition of the above-described ion implantation of the p-type impurity. As ionic species, boron difluoride (BF2⁺) is used in the examinations Nos. 1 to 12, and phosphorus (P⁺) is used in the examination No. 13. “Rs” is the sheet resistance (Ω/square) of the silicon resistor film 5. “Rs fluctuation” is the fluctuation rate (%) of Rs when the temperature changes from 25° C. to 85° C. “TCR1” is the temperature coefficient (ppm/C) of the silicon resistor film 5, which is calculated from the “Rs fluctuation”. “WF uni.” is Rs uniformity in a wafer, and calculated by a following equation:

WF uni.=100×(max−min)/Xav(%) (1)

Here, the “max” is the maximum value of Rs in a wafer, the “min” is the minimum value of Rs in the wafer, and the “Xav” is the average value of RS in the wafer. Thirty eight test specimens were cut out from a single wafer for each of the examinations 1-13.

In the examinations Nos. 1 to 5, an amorphous silicon film (α-Si film) is used as the silicon film 3. In the examinations Nos. 6 to 13, a polysilicon film (Poly-Si film) is used as the silicon film 3. The thickness of the films in the examinations Nos. 1 to 13 is constant at 150 nm. The conditions of processing except the conditions shown in FIG. 7 are the same among the examinations. The thickness of the TEOS film 6 was 200 nm, the thickness of the BPSG film 7 was 1000 nm, and the deposition temperature for the BPSG film 7 was 850° C.

Here, the criteria for evaluating the property of the resistor element to be used for the LSI circuit are determined as follows. That is, Rs is 600 Ω/□ or more, the Rs fluctuation is 3% or less, and the temperature coefficient TCR1 is 600 ppm/° C. or less, and Rs uniformity in a wafer is between plus and minus 3%.

The examinations which satisfy those criteria among the above examination results are the examinations Nos. 1, 2, 4, 5, 6, 7, 9 and 10. Rs can increase when N₂ annealing at a high temperature of 900° C. is performed after ion implantation of BF2⁺ (examinations Nos. 3, 8). However, the Rs fluctuation and the temperature coefficient TCR1 increase with this annealing so that the uniformity in a wafer WF uni. decreases, not satisfying the criteria.

On the other hand, good results can be obtained from the examinations in which N₂ annealing is performed at a low temperature of 700° C. both after (examination Nos. 1, 2, 6, 7) and before (examination Nos. 5, 10) the ion implantation of BF2⁺. The examinations in which N₂ annealing is not performed (examination Nos. 4, 9) also show properties satisfying the criteria, though not as good as the above examinations performed with N₂ annealing at the low temperature.

The N₂ annealing at the high temperature of 900° C. with the silicon film 3 being exposed makes diffusion of BF2⁺, which is ion implanted in the silicon film 3, non-uniform in a wafer, so that the uniformity in a wafer WF uni. decreases, affecting the temperature coefficient TCR1. On the contrary, the N₂ annealing at the low temperature of approximately 700° C. makes diffusion of BF2⁺ uniform and provides the moderate annealing effect, that is, providing good properties. This N₂ annealing at low temperature is performed appropriately at substantially lower temperature than 900° C., preferably between 650 and 750° C.

The examinations performed with the N₂ annealing at 700° C. after ion implantation of BF2⁺ show better properties than the ones performed with N₂ annealing before ion implantation of BF2⁺ in all the features including Rs, the Rs fluctuation, the temperature coefficient TCR1 and the uniformity in a wafer WF uni. (examinations Nos. 1, 2, 6, 7).

Comparing the amorphous silicon film (examinations Nos. 1, 2, 5) to the polysilicon film (examinations Nos. 6, 7, 10) used as the silicon film 3, under the condition that the N₂ annealing is performed at 700° C., the examinations using the polysilicon film is higher and superior in Rs, but in the other properties (Rs fluctuation, temperature coefficient TCR1 and uniformity in a wafer WF uni.) the examinations using the amorphous silicon film is superior.

Incidentally, the results of the examinations Nos. 11, 12, 13 do not satisfy the above evaluation criteria. The reason is that the dose of BF2⁺ is insufficient in the examinations Nos. 11, 12 so that the Rs fluctuation and the temperature coefficient TCR1 increase. In the examination No. 13, Rs decreases since phosphorus (P⁺) is used as ion species, and the temperature coefficient TCR1 increases since the dose of phosphorus (P⁺) is insufficient.

What is claimed is:

1. A method of manufacturing a semiconductor device, comprising:
forming a first insulating film on a semiconductor substrate;
forming a non-doped silicon film on the first insulating film;
performing an ion implantation of a p-type impurity in the silicon film;
annealing the ion-implanted silicon film in a nitrogen atmosphere at such a temperature that the p-type impurity implanted in the silicon film is diffused uniformly in the semiconductor substrate while the silicon film is exposed to the nitrogen atmosphere; and
forming a second insulating film on the silicon film.

2. The method of manufacturing a semiconductor device of claim 1, wherein the temperature is 750° C. or lower.

3. The method of manufacturing a semiconductor device of claim 2, wherein the temperature is 650° C. or higher.

4. The method of manufacturing a semiconductor device of claim 1, wherein the silicon film comprises an amorphous silicon film.

5. The method of manufacturing a semiconductor device of claim 1, wherein the silicon film comprises a polysilicon film.

6. The method of manufacturing a semiconductor device of claim 1, wherein the p-type impurity is BF₂⁺.

7. The method of manufacturing a semiconductor device of claim 1, further comprising performing a further annealing in a hydrogen atmosphere after performing the annealing in the nitrogen atmosphere.

8. A method of manufacturing a semiconductor device, comprising:
forming a first insulating film on a semiconductor substrate;
forming a non-doped silicon film on the first insulating film;
performing an annealing of the silicon film in a nitrogen atmosphere at a temperature between 650 and 750° C. while the silicon film is exposed to an ambient atmosphere;
performing an ion implantation of a p-type impurity in the annealed silicon film; and
forming a second insulating film on the silicon film.

9. The method of manufacturing a semiconductor device of claim 8, wherein the silicon film comprises an amorphous silicon film.

10. The method of manufacturing a semiconductor device of claim 8, wherein the silicon film comprises a polysilicon film.

11. The method of manufacturing a semiconductor device of claim 8, wherein the p-type impurity comprises BF₂⁺.

12. The method of manufacturing a semiconductor device of claim 8, further comprising performing a further annealing in a hydrogen atmosphere after performing the annealing in the nitrogen atmosphere.

13. A method of manufacturing a semiconductor device, comprising:
forming a first insulating film on a semiconductor substrate;
forming a non-doped silicon film on the first insulating film;
performing ion implantation of a p-type impurity in the silicon film; and
forming a second insulating film on the silicon film without annealing the silicon film while the silicon film is exposed to an ambient atmosphere.

14. The method of manufacturing a semiconductor device of claim 13, wherein the silicon film comprises an amorphous silicon film.

15. The method of manufacturing a semiconductor device of claim 13, wherein the silicon film comprises a polysilicon film.

16. The method of manufacturing a semiconductor device of claim 13, wherein the p-type impurity comprises BF₂⁺.

17. The method of manufacturing a semiconductor device of claim 16, wherein a dose of BF₂⁺ is between 5×10¹⁵/cm² and 1.5×10¹⁶/cm².

18. The method of manufacturing a semiconductor device of claim 13, further comprising performing an annealing in a hydrogen atmosphere.
